(19) United States
(12) Patent Application Publication
(10) Pub. No.: US 2026/0270616 A1
(43) Pub. Date: Sep. 10, 2026

(54) METHOD AND SYSTEM FOR MECHANICAL PROTECTION AND NONLINEAR COMPENSATION OF LOUDSPEAKER SYSTEMS

(71) Applicant: HARMAN INTERNATIONAL INDUSTRIES, INCORPORATED, Stamford, CT (US)

(72) Inventor: Jiahe LIU, Shenzhen, Guangdong (CN)

(73) Assignee: HARMAN INTERNATIONAL INDUSTRIES, INCORPORATED, Stamford, CT (US)

(21) Appl. No.: 19/141,706

(22) PCT Filed: Dec. 30, 2022
(86) PCT No.: PCT/CN2022/143930

§ 371 Date: Jun. 20, 2025

(51) Int. Cl. H04R 3/00; H04R 3/04

(52) U.S. Cl. CPC H04R 3/007; H04R 3/04

(57) ABSTRACT

A loudspeaker protection system includes a driver and either a passive radiator or a vent port, and a controller configured to determine a displacement of the driver and either a displacement of the passive radiator or a velocity of airflow through the port based on an input voltage representing an audible sound, and to determine an output voltage for the loudspeaker to reproduce the audible sound based on a first type of compression applied to the driver displacement and a second type of compression applied to either the passive radiator displacement or the vent port airflow velocity. The output voltage limits the driver displacement within a driver displacement range and simultaneously limits either the passive radiator displacement within a passive radiator displacement range or the vent port airflow velocity within a vent port airflow velocity range to mechanically protect the loudspeaker and reduce distortions in the audible sound reproduced.

### TECHNICAL FIELD

The present disclosure relates to a method and system for mechanical protection and nonlinear compensation of loudspeaker systems.

### BACKGROUND

Consumer audio products, or consumer electronics with embedded audio, such as smart-phones, tablets, laptops, soundbars, smart speakers and portable loudspeakers, have a general trend of being designed smaller, thinner and more compact over the last decade. Such a trend is mainly driven by industrial design considerations. However, it has a negative impact on the acoustic performance of such devices. The maximum bass outputs, the overall loudness and sound qualities are limited by the loudspeaker systems due their size constraints.

The problem is how to squeeze more bass and overall loudness out of a given loudspeaker system without damaging it or producing too much distortion. In doing so, three kinds of limits of a loudspeaker system may be considered, namely mechanical limits, nonlinear distortions, and thermal limits. The present disclosure describes methods and systems that address mechanical limits and nonlinear distortions to improve the maximum bass output and the sound quality with a given loudspeaker system.

### SUMMARY

In one non-limiting, exemplary embodiment, the present disclosure provides a loudspeaker protection. The system comprises a loudspeaker comprising a driver and either a passive radiator or a vent port, and a controller configured to determine a displacement of the driver and either a displacement of the passive radiator or a velocity of airflow through the vent port based on an input voltage representing an audible sound, and configured to determine an output voltage for the loudspeaker to reproduce the audible sound based on a first type of compression applied to the driver displacement and a second type of compression applied to either the passive radiator displacement or the vent port airflow velocity, the second type of compression different than the first type of compression. The output voltage provided to the loudspeaker limits the driver displacement within a driver displacement range and simultaneously limits either the passive radiator displacement within a passive radiator displacement range or the vent port airflow velocity within a vent port airflow velocity range to mechanically protect the loudspeaker and reduce distortions in the audible sound reproduced by the loudspeaker.

In another non-limiting, exemplary embodiment, the present disclosure provides a method for mechanically protecting a loudspeaker comprising a driver and either a passive radiator or a vent port. The method comprises determining a displacement of the driver and either a displacement of the passive radiator or a velocity of airflow through the vent port based on an input voltage representing an audible sound, and determining an output voltage for the loudspeaker to reproduce the audible sound based on a first type of compression applied to the driver displacement and a second type of compression applied to either the passive radiator displacement or the vent port airflow velocity, the second type of compression different than the first type of compression. The method further comprises providing the output voltage to the loudspeaker to limit the driver displacement within a driver displacement range and to simultaneously limit either the passive radiator displacement within a passive radiator displacement range or the vent port airflow velocity within a vent port airflow velocity range to mechanically protect the loudspeaker and reduce distortions in the audible sound reproduced by the loudspeaker.

In another non-limiting, exemplary embodiment, the present disclosure provides a non-transitory computer readable medium having stored computer executable instructions for mechanically protecting a loudspeaker comprising a driver and either a passive radiator or a vent port. Execution of the instructions causes a controller to determine a displacement of the driver and either a displacement of the passive radiator or a velocity of airflow through the vent port based on an input voltage representing an audible sound, determine an output voltage for the loudspeaker to reproduce the audible sound based on a first type of compression applied to the driver displacement and a second type of compression applied to either the passive radiator displacement or the vent port airflow velocity, the second type of compression different than the first type of compression, and provide the output voltage to the loudspeaker to limit the driver displacement within a driver displacement range and to simultaneously limit either the passive radiator displacement within a passive radiator displacement range or the vent port airflow velocity within a vent port airflow velocity range to mechanically protect the loudspeaker and reduce distortions in the audible sound reproduced by the loudspeaker.

A detailed description of these and other non-limiting exemplary embodiments of systems and methods of the present disclosure is set forth below together with the accompanying drawings.

### BRIEF DESCRIPTION OF THE DRAWINGS

FIGS. 1A-1C are cross-sections of non-limiting, exemplary closed-box, passive radiator, and vented-box loudspeaker systems;

FIG. 2 is a cross-section of a non-limiting, exemplary loudspeaker driver;

FIG. 3 is a graph illustrating an example of a displacement dependent Bl factor in a loudspeaker;

FIGS. 4A and 4B are illustration relating to mechanical protection for bass enhancement in a loudspeaker;

FIGS. 5A and 5B illustrate measured loudspeaker driver displacement over time in a commercial product using a known voltage-controlled limiter;

FIG. 6 is a simplified block diagram of a non-limiting, exemplary embodiment of the method and system according to the present disclosure;

FIG. 7 is a simplified block diagram of a model-driven side-chain dynamic range controller (DRC) according to a non-limiting, exemplary embodiment of the method and system of the present disclosure;

FIG. 8 is a simplified block diagram of direct compression of mechanical signals according to a non-limiting, exemplary embodiment of the method and system of the present disclosure;

FIG. 9 is a simplified block diagram of a model-driven side-chain dynamic range controller (DRC) for a passive radiator loudspeaker according to a non-limiting, exemplary embodiment of the method and system of the present disclosure;

FIGS. 10A-10G are signal diagrams illustrating an example with music input for the model-driven side-chain DRC of FIG. 9;

FIGS. 11A and 11B are signal diagrams illustrating an example with music input for the model-driven side-chain DRC for a passive radiator loudspeaker shown in FIG. 9;

FIG. 12 is a simplified block diagram of a model-driven side-chain DRC for a vented-box loudspeaker according to a non-limiting, exemplary embodiment of the method and system of the present disclosure;

FIGS. 13A and 13B are a simplified block diagram of a direct mechanical compression for a passive radiator loudspeaker according to a non-limiting, exemplary embodiment of the method and system of the present disclosure;

FIGS. 14A-14F are signal diagrams illustrating an example with music input for the direct mechanical compression for a passive radiator loudspeaker shown in FIG. 13;

FIG. 15 is a simplified block diagram of a direct mechanical compression system with voltage limits according to a non-limiting, exemplary alternative embodiment of the systems and methods of the present disclosure;

FIG. 16 is a simplified block diagram of a directed mechanical compression system for a vented-box loudspeaker system according to a non-limiting, exemplary alternative embodiment of the systems and methods of the present disclosure;

FIG. 17 is an exemplary a graph of the magnitude of displacement transfer functions of a passive radiator loudspeaker system;

FIG. 18 is a table describing various features of model-driven side-chain DRC and direct compression methods and systems according to the present disclosure;

FIG. 19 is a simplified block diagram of a non-limiting, exemplary embodiment of a hybrid method and system for signal processing to provide mechanical protection in a PR loudspeaker system according to the present disclosure;

FIG. 20 is a simplified block diagram of another non-limiting, exemplary embodiment of a hybrid method and system for signal processing to provide mechanical protection in a PR loudspeaker system according to the present disclosure;

FIGS. 21A-21F are signal diagrams illustrating an example with music input of the hybrid method for signal processing to provide mechanical protection in a passive radiator loudspeaker system shown in FIG. 19;

FIG. 22 depicts signal diagrams illustrating an example with music input of the hybrid method for signal processing to provide mechanical protection in a passive radiator loudspeaker system shown in FIG. 19;

FIG. 23 is a simplified block diagram of multi-band and multi-stage protection for a PR loudspeaker system according to a non-limiting, exemplary alternative embodiment of the systems and methods of the present disclosure;

FIG. 24 is a simplified block diagram of a concept of nonlinear compensation of a loudspeaker;

FIG. 25 is a simplified block diagram of nonlinear compensation for a PR loudspeaker system according to a non-limiting, exemplary embodiment of the present disclosure;

FIG. 26 is a simplified block diagram of nonlinear compensation integration with direct mechanical compression in a PR loudspeaker system according to a non-limiting, exemplary embodiment of the method and system of the present disclosure;

FIG. 27 is a simplified block diagram of nonlinear compensation integration with a hybrid method of direct compression of loudspeaker driver displacement and side-chain limiting for loudspeaker passive radiator displacement in a PR loudspeaker system according to a non-limiting, exemplary embodiment of the method and system of the present disclosure; and

FIG. 28 is a simplified block diagram of nonlinear compensation integration with mechanical protection for a PR loudspeaker system according to another non-limiting, exemplary embodiment of the method and system of the present disclosure.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

The maximum bass output of consumer audio products is often limited by their loudspeaker systems due their size constraints. More specifically, there are the displacement limits of the loudspeaker diaphragm and the passive radiators, and the velocity limits of the vent air. In addition, the loudspeaker drivers produce distortions at large displacement, which act as a “soft” limit of the displacement. As a result, many consumer audio products suffer from a lack of bass due to the mechanical limits of their loudspeaker system. Moreover, the available mechanical dynamic range are often not fully used with common post-processing methods.

The present disclosure describes methods and systems that improve the bass performance of loudspeaker systems by fully exploiting the available mechanical dynamic range. The present disclosure describes signal-processing-based methods and systems that provide mechanical protection and nonlinear compensation to a loudspeaker system. With accurate protection, the peaks in the displacement or velocity responses are suppressed. In this way, the input gain can be safely increased to push a loudspeaker system to its mechanical limits. The rms value of the acoustic output is also increased and so is the subjective loudness. Moreover, nonlinear compensation is combined to actively reduce the distortions at large volume.

The method is based on real-time modeling of the loudspeaker systems. The parameters of the model can be updated in real-time with voltage and current measurements to track the parameter changing and compensate for production variance. If the model parameters are well-known, or more protection margin is allowed, the real-time parameter updating may be omitted.

The present disclosure describes methods and systems for mechanical protection and nonlinear compensation for Vented-box or PR Loudspeaker systems. With these methods and systems, loudspeaker systems can be safely pushed to their mechanical limits without the risk of being damaged. The nonlinear distortions can be actively reduced to exploit the nonlinear working range. Compared to known methods and systems, the methods and systems according to the present disclosure can simultaneously protect displacement of the loudspeaker driver and passive radiator, as well as the vent velocity, and are well integrated with the nonlinear compensation.

The methods and systems of the present disclosure provide protection and compensation to loudspeaker systems. More specifically, the methods and systems of the present disclosure increase the maximum bass output and improve the sound qualities at high volume for a given loudspeaker system. In that regard, the methods and systems of the present disclosure squeeze more bass and overall loudness out of a given loudspeaker system without damaging it or producing too much distortion. The methods and systems of the present disclosure described herein can be used for loudspeaker systems of any size, ranging from portable products to large subwoofers, and result in a huge and clean bass produced from a loudspeaker with a relatively small form factor that performs beyond user expectations. The methods and systems of the present disclosure increase the maximum bass output of a given loudspeaker system, protect the loudspeaker system from any mechanical damage, and enable the size of loudspeaker systems to be reduced while maintaining the bass performance.

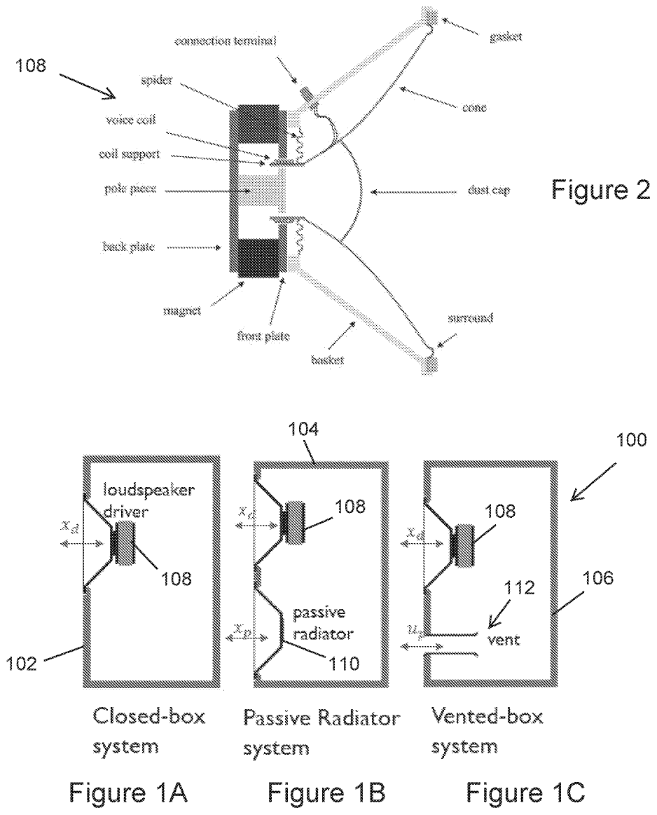

FIGS. 1A-1C are cross-sections of non-limiting, exemplary loudspeaker systems 100, including a closed-box system 102, a passive radiator (PR) system 104, and a vented-box system 106. Each of the systems 102, 104, 106 includes a loudspeaker driver 108. The PR system 104 also includes a passive radiator 110, and the vented-box system 106 also includes a vent or port 112. A cross-section of a non-limiting, exemplary loudspeaker driver 108 common to each of the systems 102, 104, 106 is shown in FIG. 2.

As shown in FIGS. 1A-1C, operation of each system 102, 104, 106 results in displacement of the driver 108. As seen in FIG. 1B, operation of the PR system 104 results in displacement of the passive radiator 110. As shown in FIG. 1C, operation of the vented-box system 106 results in an airflow having a velocity through the vent port 112. In that regard, frequently used symbols and abbreviations used herein are as follows:
x_{d} displacement of the loudspeaker driver diaphragm
xₚ displacement of the passive radiator
uₚ velocity of the port (vent) in the vented-box system
EQ Equalizer filters
PR Passive Radiator
DRC Dynamic Range Control/Controller

Mechanical limitations associated with one or more of the loudspeaker systems 102, 104, 106 include: (1) Physically allowable moving range of the moving parts (before hitting other parts or the suspension being fully stretched), i.e., the limit on the loudspeaker driver displacement (x_{d}) and the passive radiator displacement (xₚ); and (2) Large air velocity can cause turbulent flow noise, i.e., the limit on the vent air velocity (uₚ). Since large x_{d}, xₚ and uₚ all occur at low frequency range, the mechanical limits affect the maximum bass output.

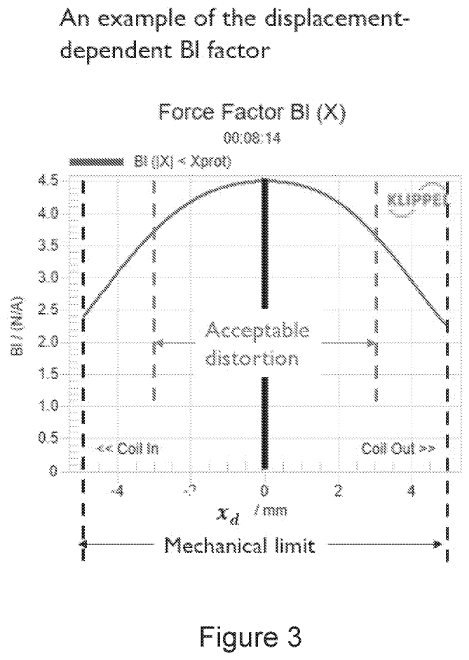

Regarding nonlinear distortions, loudspeakers are inherently nonlinear because many of the parameters depend on the states of the system 102, 104, 106. The most dominant nonlinearities are: (1) Bl(x) (Force Factor or Speaker Motor Strength, which is a product of the strength of the magnetic field (B) in the voice coil and the length (l) of the voice coil); (2) Kms(x) (Speaker Suspension Stiffness (inverse of compliance)); (3) Le(x) (Voice coil inductance); and (4) Rms(v) (Mechanical resistance). Nonlinear distortions affect the full-band sound quality due to the produced harmonic and inter-modulation distortions at large signals. Since the nonlinearities are mostly displacement-dependent, it is also a limiting factor of the maximum bass output. FIG. 3 is a graph illustrating an example of a displacement dependent Bl factor in a loudspeaker.

Music contents have very large dynamic range and crest factor, i.e., they have large peak values and relatively low Root Mean Square (rms) values. The same is true for the corresponding waveforms of x_{d}, xₚ, and uₚ. The maximum bass output of a loudspeaker system is limited by the peaks that can cause mechanical overloads and excessive distortions. However, the human perceived loudness is more related to the rms value in a longer period.

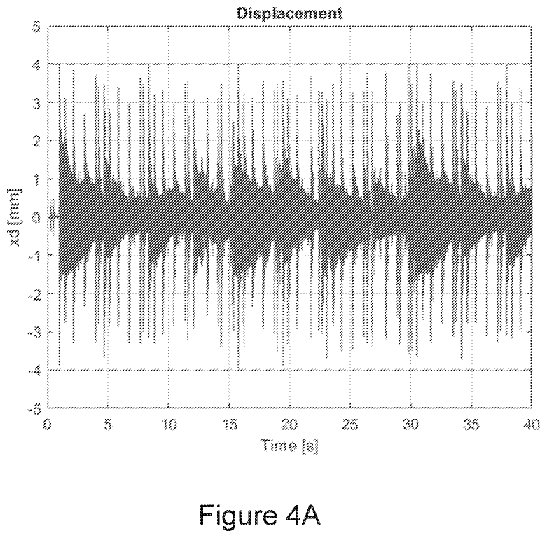

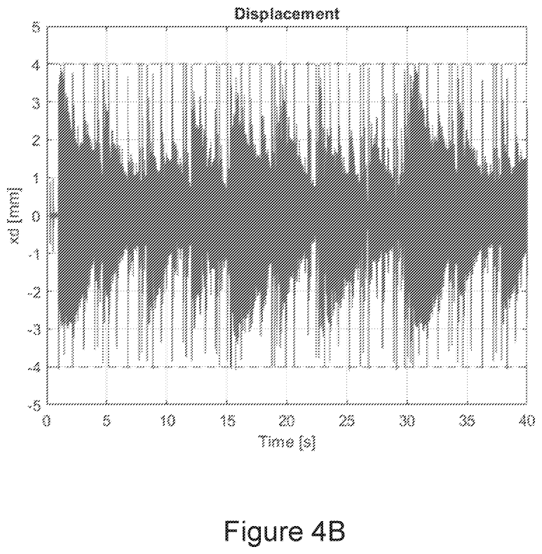

The basic idea of the present disclosure is to reduce the dynamic range in x_{d}, xₚ, and uₚ by mechanical overload protection, which can be seen as a special kind of DRC that suppress the peaks and boost the rms values. In addition, nonlinear compensation can be used to actively reduce the distortions at large displacement. FIGS. 4A and 4B are illustrations relating to mechanical protection for bass enhancement in a loudspeaker. FIG. 4A shows maximum driver displacement, x_{d}, without mechanical protection over time (0-40 seconds), while FIG. 4B shows driver displacement, x_{d}, of the same input over time with extra gain and mechanical protection. With protection, the input gain can be safely increased. In the example shown, the displacement limit is ±4 mm and the rms values is increased by 4 dB.

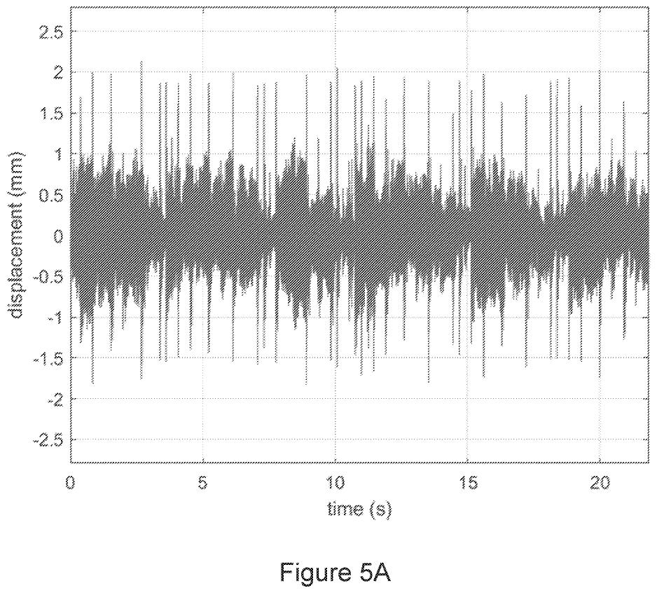

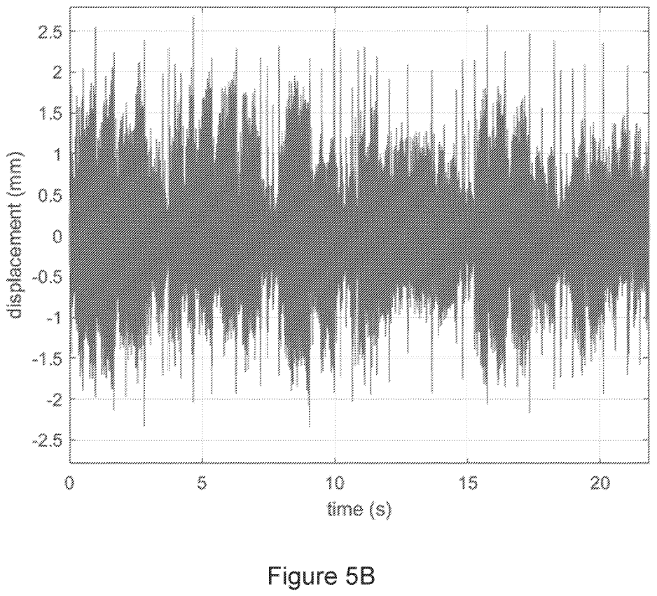

Known voltage-controlled limiters split the low-frequency band and compress it based on the peak voltage. Methods using voltage-controlled limiters are disclosed in U.S. Pat. Nos. 9,380,385B1, 9,917,565B2, and 9,967,655B2, which are hereby incorporated by reference herein in their entireties. However, problems associated with such methods include that the dynamics of the loudspeaker systems are either not considered or over-simplified. The protection cannot be accurate. It is essentially tuned for the worst-case scenario, leaving a large safety margin. Additional problems are that tuning is difficult, relying on trial and error, and they can do nothing about the nonlinear distortion. FIGS. 5A and 5B illustrate measured loudspeaker driver displacement over time in a commercial product using a known method with a voltage-controlled limiter. In that regard, FIG. 5A shows medium volume with little compression, while FIG. 5B shows maximum volume. As seen in FIG. 5B, the dynamic range is not fully utilized and displacement is over-compressed for most of the time.

Model-based methods for closed-box systems use a real-time loudspeaker model to predict and compress (limit) the driver displacement. The methods can be roughly divided into two categories: (1) Variable low-frequency EQ or side-chain DRC driven by loudspeaker models, such as those described in U.S. Pat. Nos. 7,372,966B2, 9,980,068B2, 10,206,038B2, 10,462,565B2, 10,536,774B2, and 10,701,485B2, which are hereby incorporated by reference herein in their entireties; and (2) Direct x_{d} compressing followed by inverse modeling, such as those described in U.S. Pat. Nos. 8,712,065B2, 9,837,971B2, 9,967,663B2, and 10,165,361B2, which are hereby incorporated by reference herein in their entireties. Such methods have been widely used for closed-box micro-loudspeakers on devices such as smart phones and tablets. They are commonly known as SmartPA technology. Nonlinear compensation can also be integrated with the driver displacement protection, such as described in U.S. Pat. No. 10,547,942B2, which is hereby incorporated by reference herein in its entirety. However, a problem with the prior art models and systems using direct x_{d} compressing followed by inverse modeling is that they only work for closed-box system.

Model-based methods for vented-box and PR systems may be categorized as follows. For vented-box and PR system, combine a trajectory planning block that gives the target displacement and a feedforward control block that converts the target displacement to control voltage, such as described in U.S. Pat. No. 10,506,347B2, which is hereby incorporated by reference herein in its entirety. However, how to generate the target displacement to match the system limit is not described, and the limit of the port velocity is not considered. For vented-box systems, an alternative is to limit the port velocity by side-chain DRC driven by total port energy, such as described in U.S. Pat. No. 10,797,666B2, which is hereby incorporated by reference herein in its entirety. While the energy-driven DRC described there potentially has a smoother gain curve, it comes at a slightly higher computational cost, and how to limit x_{d} at the same time is not mentioned. Another alternative for vented-box systems is to focus protecting loudspeaker driver displacement without regard to vent velocity, such as described in US2022/0201386A1, which is hereby incorporated by reference herein in its entirety. For PR system, an alternative is to compress modeled x_{d} directly and convert back to voltage, such as described in U.S. Pat. No. 11,399,247B2, which is hereby incorporated by reference herein in its entirety. As described therein, however, how to limit xₚ at the same time is not mentioned.

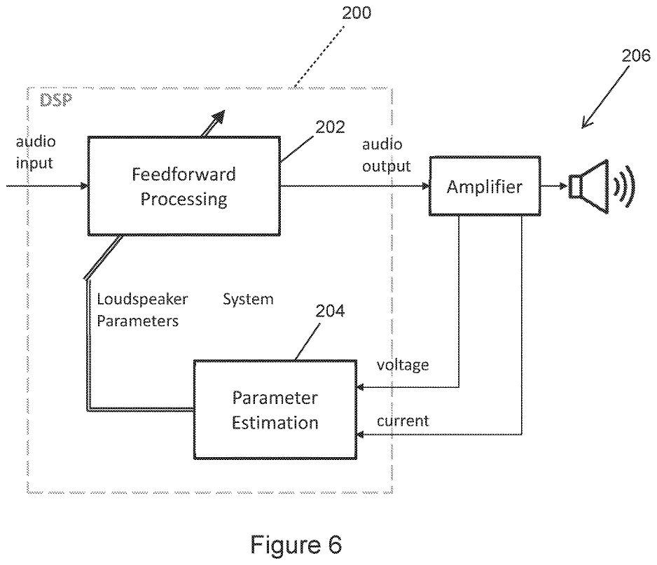

In contrast, FIG. 6 is a simplified block diagram of a non-limiting, exemplary embodiment of the method and system according to the present disclosure. As seen therein, the method and system for loudspeaker protection according to the present disclosure generally comprises a DRC or controller 200, such as a Digital Signal Processor (DSP), configured to receive a varying input voltage of audio signal representing an audible sound. The controller 200 includes a software-based solution comprising feedforward processing 202 for mechanical overload protection and nonlinear compensation, as well as parameter estimation 204 for real-time update of the model parameters. According such a software-based solution, the controller 200 provides a varying output voltage of an audio signal for reproduction of the audible sound by a loudspeaker 206.

In that regard, the present disclosure centers around real-time modeling of loudspeaker systems. The parameter estimation block 204 is provided to correct the errors in model parameters caused by various time-varying effects and production variance. The present disclosure provides the following features: (1) Applicability to PR and vented-box loudspeaker systems; (2) Simultaneous protection of x_{d}, xₚ, uₚ; (3) Maximized bass output; and (4) Reduced distortion without reducing the output. The present disclosure also increases the maximum bass output of a given loudspeaker system, protects the loudspeaker system from any mechanical damage, and enables the size of loudspeaker systems to be reduced while maintaining the bass performance.

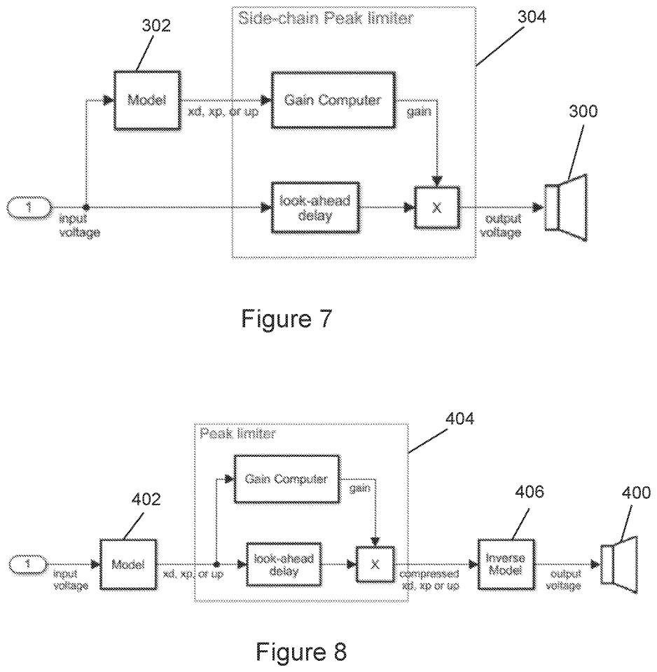

The methods and systems according to the present disclosure may be built upon two basic ideas. First, FIG. 7 is a simplified block diagram of a model-driven side-chain DRC according to a non-limiting, exemplary embodiment of the method and system of the present disclosure. As seen therein, the method and system for mechanical protection of a loudspeaker 300 may comprise a loudspeaker model module 302 and a side-chain peak limiter 304. Second, FIG. 8 is a simplified block diagram of direct compression of mechanical signals according to a non-limiting, exemplary embodiment of the method and system of the present disclosure. As seen therein, the method and system for mechanical protection of a loudspeaker 400 may comprise a loudspeaker model module 402, a peak limiter 404, and an inverse loudspeaker model module 406. It is noted that these two types of methods and systems are not mutually exclusive, and can be combined in many ways.

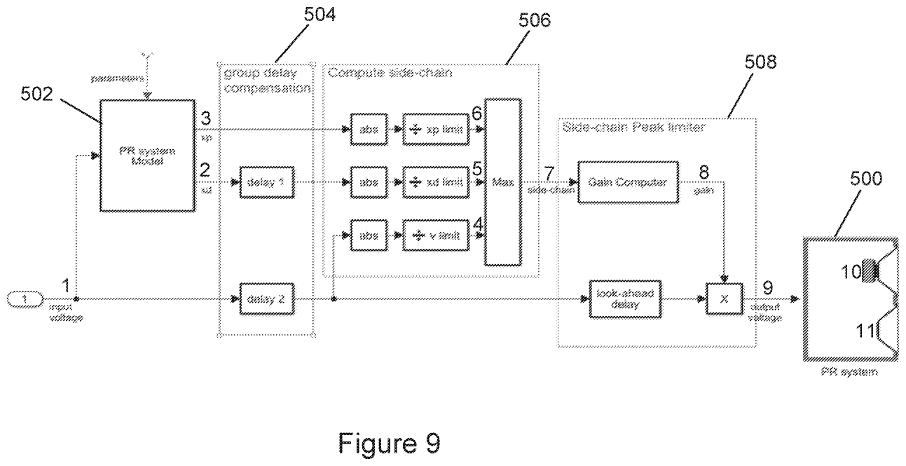

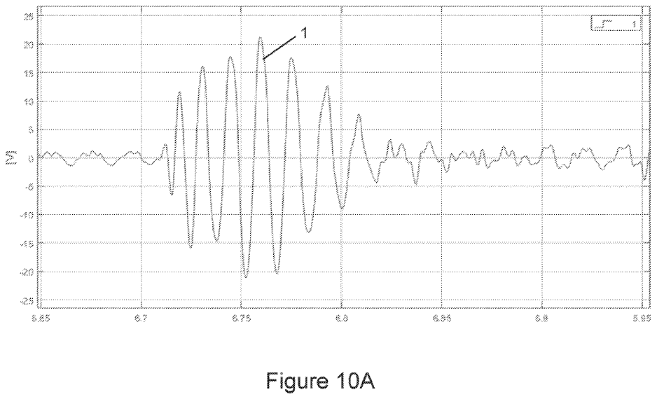

FIG. 9 is a simplified block diagram of a model-driven side-chain DRC for PR loudspeaker systems according to a non-limiting, exemplary embodiment of the method and system of the present disclosure. As seen therein, the model-driven side-chain DRC for mechanical protection of a PR loudspeaker system 500 may comprise a PR system model module 502, which is a digital model that produces x_{d} and xₚ from an input voltage. The module 502 may or may not receive model parameter updates from outside, and may be linear or nonlinear depending on the needs. The model-driven side-chain DRC may also comprise an optional group delay compensation block 504, which compensates for the group delay differences. In that regard, since group delay is frequency dependent, an averaged value in the interested frequency band may be used.

The model-driven side-chain DRC may further comprise a side-chain block 506 for computing xₚ, x_{d}, and voltage (v) side-chains. The side-chain block 506 may, for each signal (xp, xd, v), take the absolute value and then normalize it by a corresponding threshold (limit). The largest value among the three (xp, xd, v) is the side-chain input to a peak limiter 508, which detects the peak values exceeding the corresponding threshold and computes the gain accordingly. Since the side-chain has been normalized, the threshold may be set to 1 (0 dB).

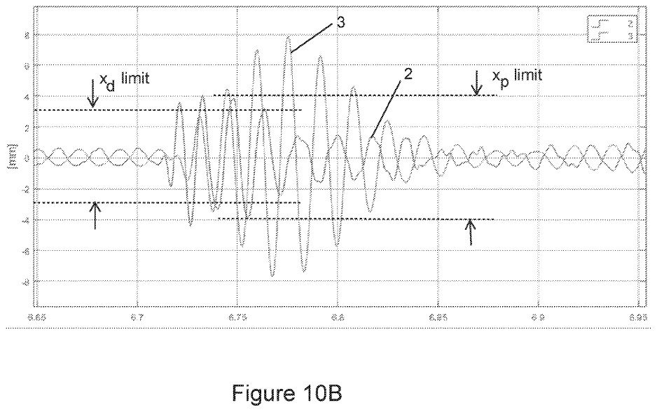

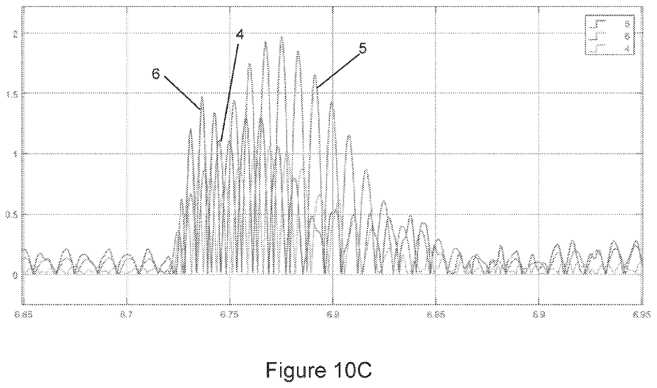

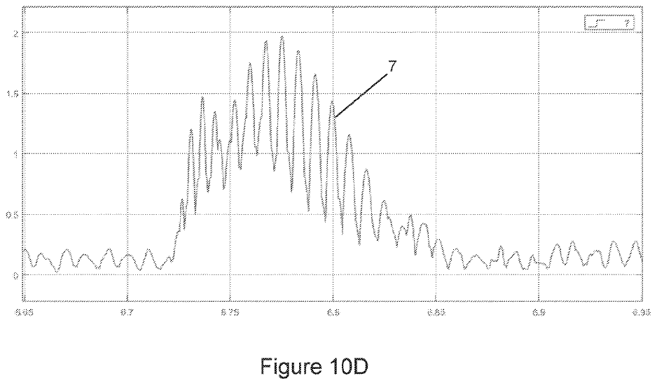

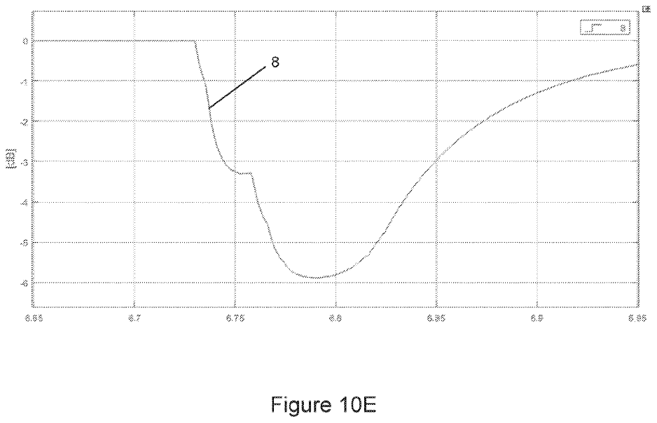

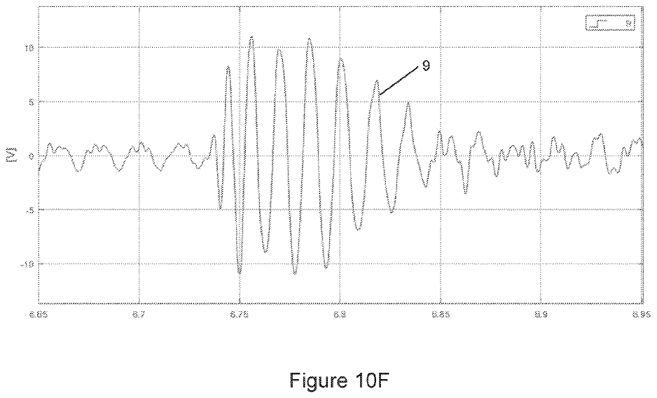

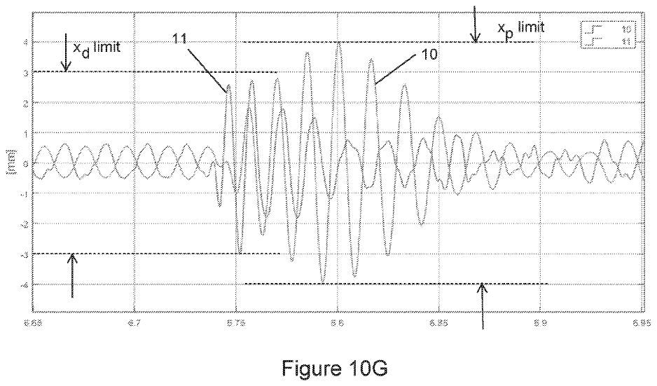

An example with music input for the model-driven side-chain DRC of FIG. 9 is shown in the signal diagrams of FIGS. 10A-10G. In the example shown, the protection setup includes an x_{d} limit of +/−3 millimeters (mm), an xₚ limit of +/−4 mm, and voltage limit of +/−20 volts (V). The signals as a function of time shown in FIGS. 10A-10G are labeled in FIG. 9 with the numerals 1-11. Thus, FIG. 10A shows the input voltage 1, and FIG. 10B shows unprotected x_{d} and xₚ values 2, 3, which may exceed the protection setup limits. FIG. 10C shows the normalized values of x_{d}, xₚ, and voltage (v) 4, 5, 6 computed by side-chain block 506, while FIG. 10D shows the maximum side-chain value (x_{d}, xₚ, or v) 7. FIG. 10E shows the gain applied to the voltage 8, while FIG. 10F shows the output voltage 9 provided to the PR loudspeaker 500, which as can be seen is consistently within the protection setup voltage limit. Finally, FIG. 10G shows the protected x_{d} and xₚ values 10, 11, which are also within the protection setup limits.

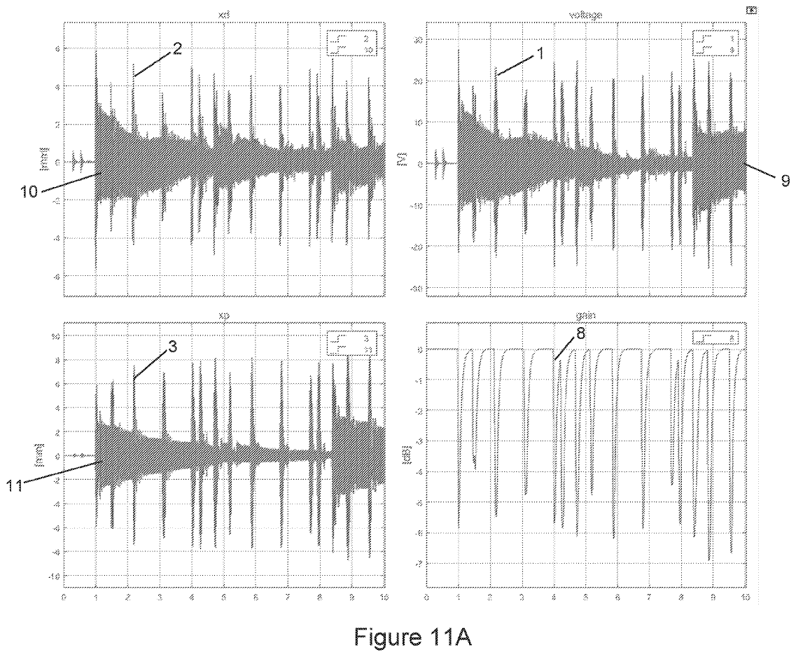

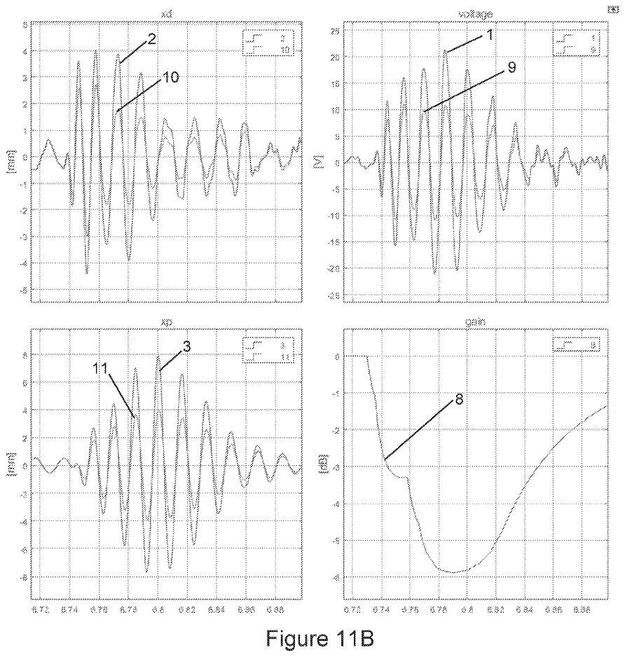

The same example with music input for the model-driven side-chain DRC of FIG. 9 is also shown in FIGS. 11A and 11B. Once again, in the example shown, the protection setup includes an x_{d} limit of +/−3 mm, an xₚ limit of +/−4 mm, and voltage limit of +/−20V. The signals as a function of time shown in FIGS. 11A and 11B are labeled in FIG. 9 with the numerals 1-3 and 8-11. Thus, the upper right graph of FIG. 11A shows the input voltage 1, which may exceed the +/−20V limit, along with the output voltage 9 provided to the PR loudspeaker 500 that is again consistently within that voltage limit. The upper left graph of FIG. 11A shows unprotected x_{d} values 2, which may exceed the +/−3 mm limit, along with the protected x_{d} values 10 that are consistently within that driver displacement limit. The lower left graph of FIG. 11A shows unprotected xₚ values 3, which may exceed the +/−4 mm limit, along with protected xₚ values 11 that are consistently within that PR displacement limit. Finally, the lower right graph of FIG. 11A shows the computed gain 8.

While FIG. 11A shows the signals noted over time from 0-10 seconds, FIG. 11B shows those same signals zoomed in at approximately the 6.8 second mark. Thus, the upper right graph of FIG. 11B once again shows the input voltage 1, which may exceed the +/−20V limit, along with the output voltage 9 provided to the PR loudspeaker 500 that is consistently within that voltage limit. The upper left graph of FIG. 11B again shows unprotected x_{d} values 2, which may exceed the +/−3 mm limit, along with the protected x_{d} values 10 that are consistently within that driver displacement limit. The lower left graph of FIG. 11B again shows unprotected xₚ values 3, which may exceed the +/−4 mm limit, along with protected xₚ values 11 that are consistently within that PR displacement limit. Finally, the lower right graph of FIG. 11A shows the computed gain 8.

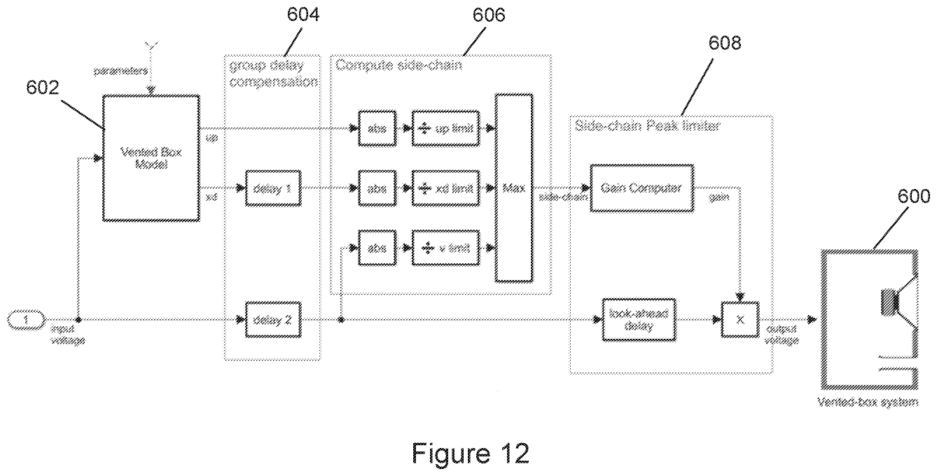

FIG. 12 is a simplified block diagram of a model-driven side-chain dynamic range controller (DRC) for a vented-box loudspeaker according to a non-limiting, exemplary embodiment of the method and system of the present disclosure. As seen therein, for a vented-box loudspeaker system 600, the system and method of the present disclosure are essentially the same as for the PR system shown in FIG. 9. In that regard, the PR loudspeaker model module may be simply replaced by a vented box model module 602 and a predicted vent velocity uₚ may be used as one of the side-chains rather than predicted PR displacement, xₚ.

Thus, as seen in FIG. 12, the model-driven side-chain DRC for mechanical protection of a vented-box loudspeaker system 600 may comprise a vented-box system model module 602, which is a digital model that produces x_{d} and uₚ from an input voltage. The module 602 may or may not receive model parameter updates from outside, and may be linear or nonlinear depending on the needs. The model-driven side-chain DRC may also comprise an optional group delay compensation block 604, which compensates for the group delay differences. In that regard, since group delay is frequency dependent, an averaged value in the interested frequency band may be used.

The model-driven side-chain DRC may further comprise a side-chain block 606 for computing uₚ, x_{d}, and voltage (v) side-chains. The side-chain block 606 may, for each signal (uₚ, x_{d}, v), take the absolute value and then normalize it by a corresponding threshold (limit). The largest value among the three (xₚ, x_{d}, v) is the side-chain input to a peak limiter 608, which detects the peak values exceeding the corresponding threshold and computes the gain accordingly. Since the side-chain has been normalized, the threshold may be set to 1 (0 dB).

While the side-chain method is simple and has short audio delay compared to the method of direct mechanical compression, it can have two disadvantages. First, the side-chain gain is biased due the loudspeaker nonlinearities. If a linear loudspeaker model is used in the side-chain, the gain would be over-estimated (too much reduction). On the other hand, using a nonlinear loudspeaker model would under-estimate the gain (not enough reduction). Second, due to the phase differences between the voltage and x_{d}, xₚ, uₚ in the side-chain, the compressed voltage may still produce mechanical overshoots. The group delay compensation previously described can greatly alleviate this problem for xₚ and uₚ. However, it cannot do much for x_{d} because its group delay varies too much in the interested frequency band.

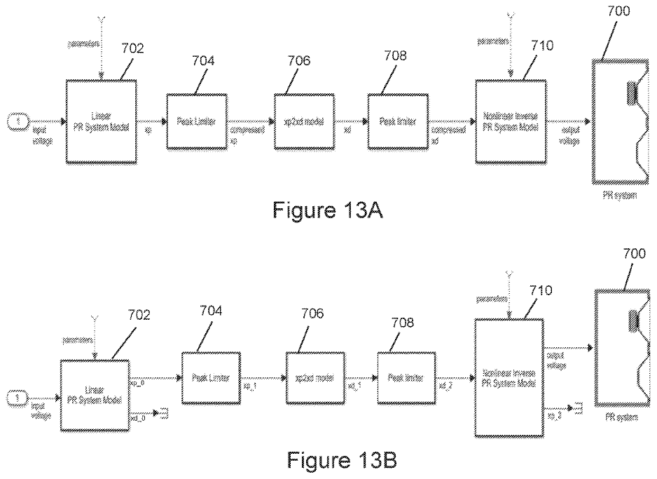

FIG. 13 is a simplified block diagram of a direct mechanical compression for a passive radiator loudspeaker according to a non-limiting, exemplary embodiment of the method and system of the present disclosure. As seen therein, direct mechanical compression for a PR loudspeaker system 700 includes a two-stage DRC system that compress the modeled x_{d} and xₚ directly and then converts back to voltage. The order of these two stages can be switched. The system may comprise a linear PR system model module 702 that produces xₚ from input voltage of an audio signal representing an audible sound and which may or may not receive parameter updates from outside. The system may also comprise a Stage 1 peak limiter 704 that compresses the xₚ signal, and a xₚ-to-x_{d} model module 706 that converts the compressed xₚ signal to the corresponding x_{d} signal. The system may further comprise a Stage 2 peak limiter 708 that compresses the x_{d} signal, and a nonlinear inverse PR system model module 710 that converts x_{d} back to an output voltage to be provided to the PR loudspeaker system 700 to reproduce the audible sound. The nonlinear inverse PR system model module 710 may or may not receive model parameter updates from outside, and may alternatively be linear rather than nonlinear depending on the needs.

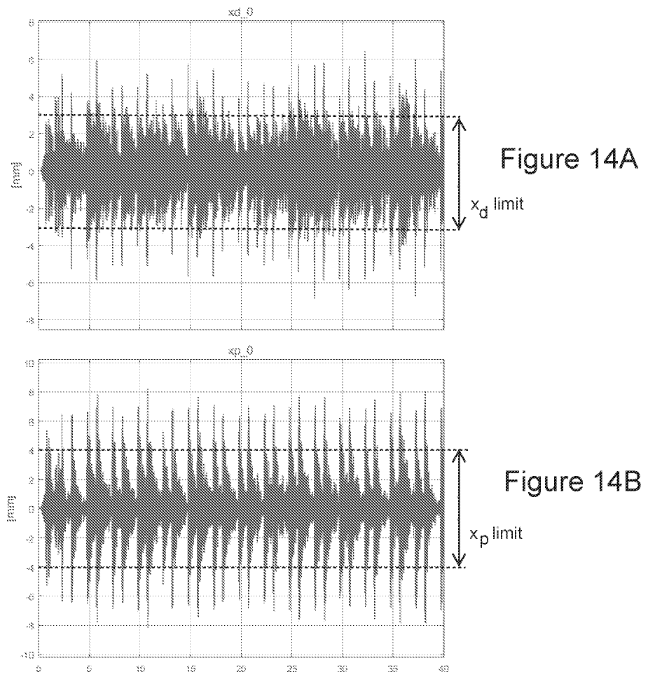

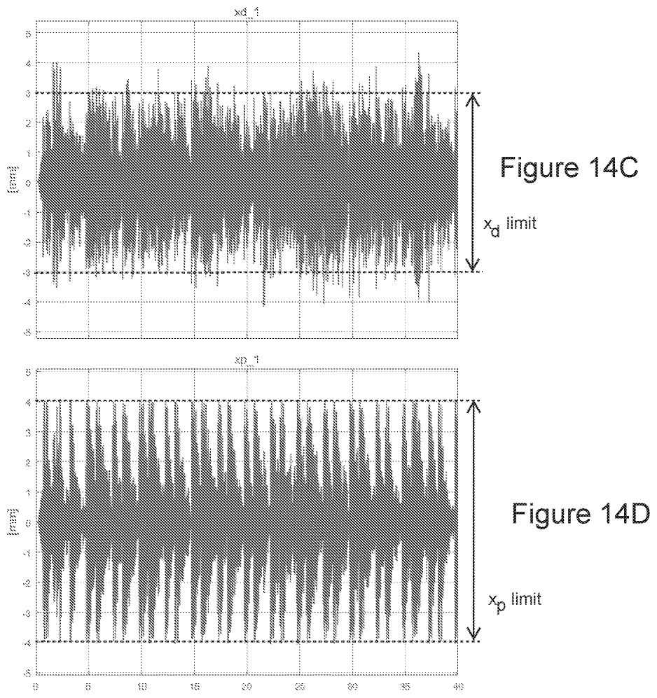

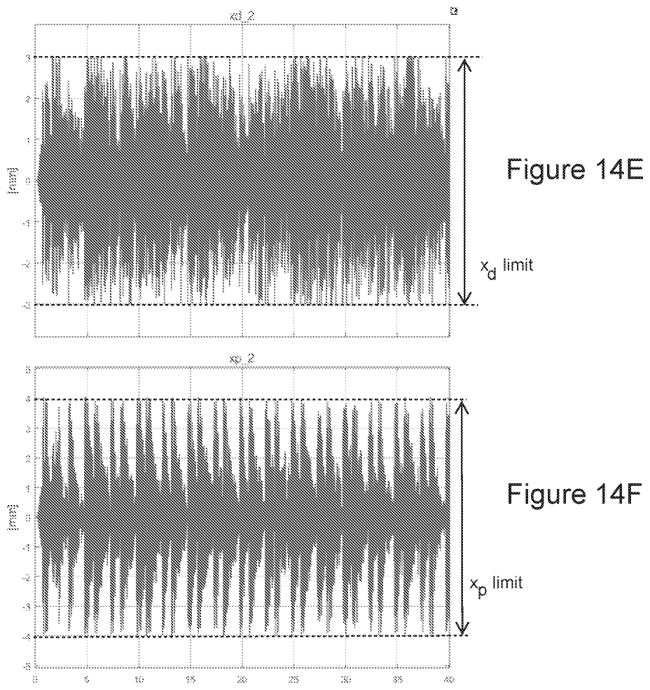

FIGS. 14A-14F are signal diagrams illustrating an example with music input for the direct mechanical compression for a PR loudspeaker shown in FIGS. 13A and 13B, which as previously described comprises a two-stage DRC system for direct mechanical compression for PR loudspeaker system 700. In the example shown, the protection setup includes an xₐ limit of +/−3 mm, and an xₚ limit of +/−4 mm. The signals as a function of time shown in FIGS. 14A-14F correspond to those labeled in FIG. 13B as xd_0, xp_0, xd_1, xp_1, xd_2, and xp_2. In that regard, FIGS. 14A and 14B show unprotected x_{d} and xₚ values (xd_0 and xp_0) output by the linear PR system model module 702 after conversion of a varying input voltage to x_{d} and xₚ, both of which may exceed their respective protection limits. FIGS. 14C and 14D show compressed xₚ values (xp_1) output by Stage 1 peak limiter 704 and compressed x_{d} values (xd_1) output by xₚ-to-x_{d} converter 706, wherein the compressed xₚ values are consistently within the xₚ protection limit. Finally, FIGS. 14E and 14F show protected x_{d} values (xd_2) output by Stage 2 peak limiter 708 and protected xₚ values (xp_2) output by the nonlinear inverse PR system model module 710, both of which are consistently within their respective protection limits.

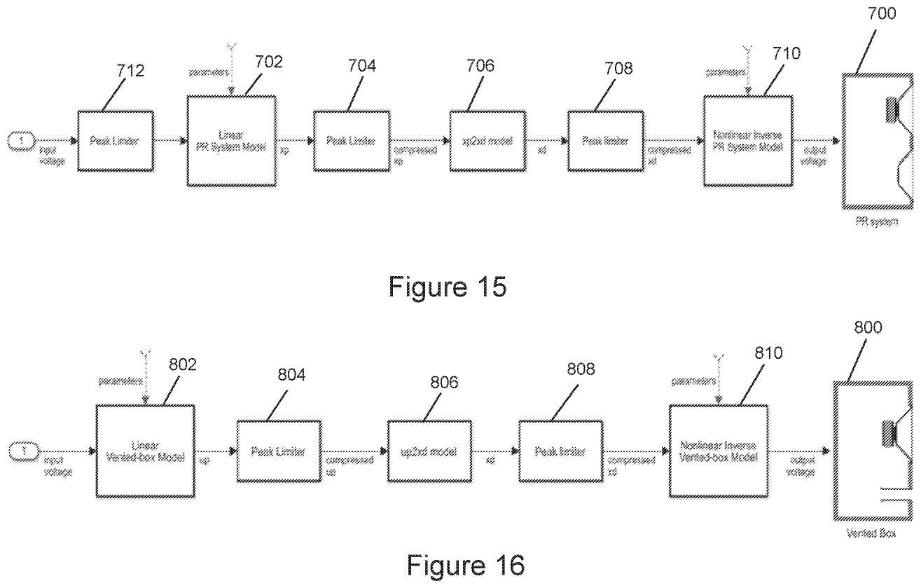

FIG. 15 is a simplified block diagram of a direct mechanical compression system with voltage limits according to a non-limiting, exemplary alternative embodiment of the systems and methods of the present disclosure. As seen therein, extensions of direct mechanical compression using voltage limits may also be employed. More specifically, as shown in FIG. 15, a voltage limit can be included by cascading another peak limiter 712 before or after the system shown in FIG. 13A. In that regard, it is noted that cascading such a voltage peak limiter after the inverse model requires the inverse model to be linear.

FIG. 16 is a simplified block diagram of a directed mechanical compression system for a vented-box loudspeaker system 800 according to a non-limiting, exemplary alternative embodiment of the systems and methods of the present disclosure. As seen therein, for a vented-box loudspeaker system 800, the modeled uₚ and x_{d} signals may be compressed. More specifically, as seen in FIG. 16, direct mechanical compression for a vented-box loudspeaker system 800 includes a two-stage DRC system that compress the modeled x_{d} and uₚ directly and then converts back to voltage. The order of these two stages can be switched. The system may comprise a linear vented-box system model module 802 that produces uₚ from a varying input voltage of an audio signal representing an audio sound and which may or may not receive parameter updates from outside. The system may also comprise a Stage 1 peak limiter 804 that compresses the uₚ signal, and an uₚ-to-x_{d} model module 806 that converts the compressed uₚ signal to the corresponding x_{d} signal. The system may further comprise a Stage 2 peak limiter 808 that compresses the x_{d} signal, and a nonlinear inverse vented-box system model module 810 that converts x_{d} back to an output voltage to be provided to the PR loudspeaker system 800 to reproduce the audible sound. The nonlinear inverse vented-box system model module 810 may or may not receive model parameter updates from outside, and may alternatively be linear rather than nonlinear depending on the needs.

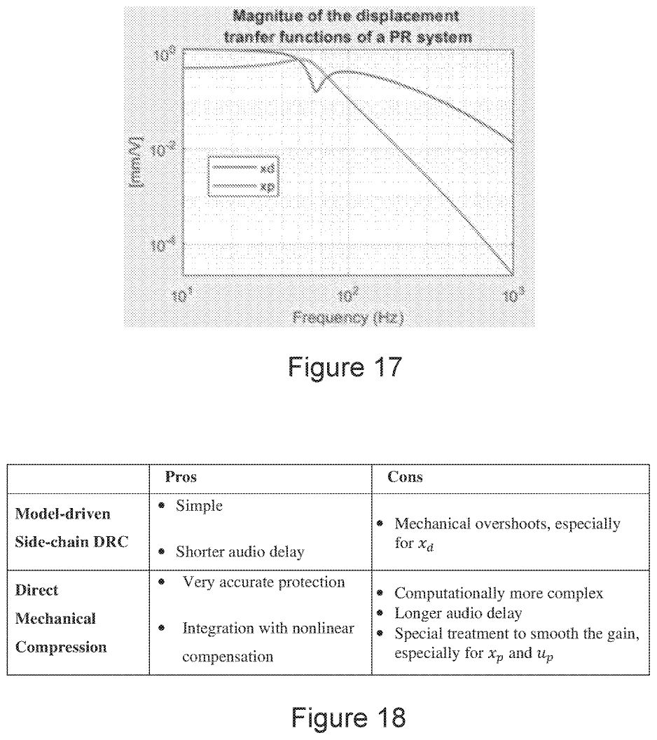

Direct mechanical compression is very accurate for protection. It is also naturally connected with nonlinear compensation as described herein. However, it is computationally heavy. Compared to the side-chain method, this method requires additionally two limiters and two loudspeaker models. In addition, this method introduces long audio delay because each of the cascaded peak limiter introduces its own look-ahead delay. Finally, special treatment is needed to ensure the gain applied to x_{d}, xₚ and uₚ being sufficiently smooth, otherwise the inverse model can produce click noises or even large spikes in the voltage. In that regard, FIG. 17 is an exemplary graph of the magnitude of displacement transfer functions of a PR loudspeaker system. As seen therein, the inverse model has large high-frequency gain. It is essentially taking high-order derivatives of the mechanical signals at high-frequency band, which reveals the high-order discontinuities introduced by the compression of x_{d}, xₚ.

According to another non-limiting, exemplary embodiment of the present disclosure, the two methods of model-driven side-chain DRC and direct compression can be combined in a hybrid fashion. The basic idea is to keep the direction compression of x_{d} and move the protection of xₚ and uₚ to the side-chains. In that regard, FIG. 18 is a table describing various features of model-driven side-chain DRC and direct compression methods and systems according to the present disclosure. Since the inversion of x_{d} to voltage has less high-frequency gain compared to xₚ and uₚ, the smoothing is less of a problem. Accurate protection and capability is also maintained for nonlinear compensation with moderate complexity and audio delay.

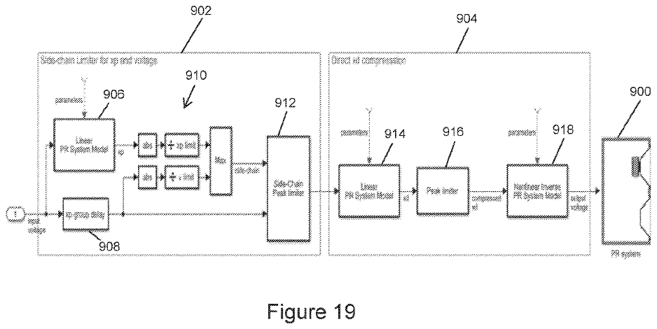

FIG. 19 is a simplified block diagram of a non-limiting, exemplary embodiment of a hybrid method and system for signal processing to provide mechanical protection in a PR loudspeaker system 900 according to the present disclosure. As seen therein, this hybrid method and system may comprise a side-chain limiter block 902 for xₚ and voltage, and a direct compression block 904 for x_{d}. The side-chain limiter block 902 may comprise a PR system model module 906, which is a digital model that produces xₚ from a varying input voltage of an audio signal representing an audible sound. The module 906 may or may not receive model parameter updates from outside, and may be linear or nonlinear depending on the needs. The side-chain limiter block 904 may also comprise an xₚ group delay block 908 to compensate for group delay differences, a side-chain block 910 for computing xₚ and voltage (v) side-chains. The side-chain block 910 may, for each signal (xp, v), take the absolute value and then normalize it by a corresponding threshold (limit). The largest value among the two (xp, v) is the side-chain input to a peak limiter 912, which detects the peak values exceeding the corresponding threshold.

The direct compression block 904 may comprise a linear PR system model module 914 that converts the signal received from the peak limiter 912 to x_{d}, and a peak limiter 916 that receives x_{d} and produces a compressed x_{d}. The direct compression block may also comprise a nonlinear inverse PR system model module 918 that converts the compressed x_{d} from the peak limiter 912 to a varying output voltage to be provided to the PR loudspeaker system 900 for reproduction of the audible sound. The module 918 may or may not receive model parameter updates from outside, and may alternatively be linear depending on the needs.

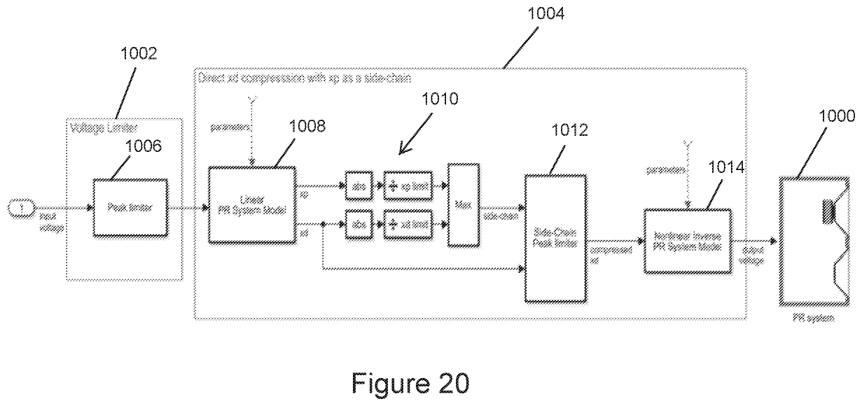

FIG. 20 is a simplified block diagram of another non-limiting, exemplary embodiment of a hybrid method and system for signal processing to provide mechanical protection in a PR loudspeaker system 1000 according to the present disclosure. As seen therein, this hybrid method and system may comprise a voltage limiter 1002 and a direct compression block 1004 with xₚ (and x_{d}) as a side-chain. The voltage limiter 1002 may comprise a peak limiter 1006 for limiting and/or compressing a varying input voltage of an audio signal representing an audible sound. The direct compression block 1004 may comprise a linear PR system model module 1008, which is a digital model that produces x_{d} and xₚ from the input voltage received from the voltage limiter 1002. The module 1008 may or may not receive model parameter updates from outside, and may be linear or nonlinear depending on the needs.

The direct compression block 1004 may further comprise a side-chain block 1010 for computing xₚ and x_{d} side-chains. The side-chain block 1010 may, for each signal (xp, xd), take the absolute value and then normalize it by a corresponding threshold (limit). The largest value among the two (xp, xd) is the side-chain input to a peak limiter 1012, which detects the peak values exceeding the corresponding threshold and outputs a compressed x_{d}. The direct compression block 1004 may further comprise a nonlinear inverse PR system model module 1014 that converts the compressed x_{d} received from the peak limiter 1012 to a varying output voltage, which is provided to the PR loudspeaker system 1000 for reproduction of the audible signal. The module 1014 may or may not receive model parameter updates from outside, and may alternatively be linear depending on the needs.

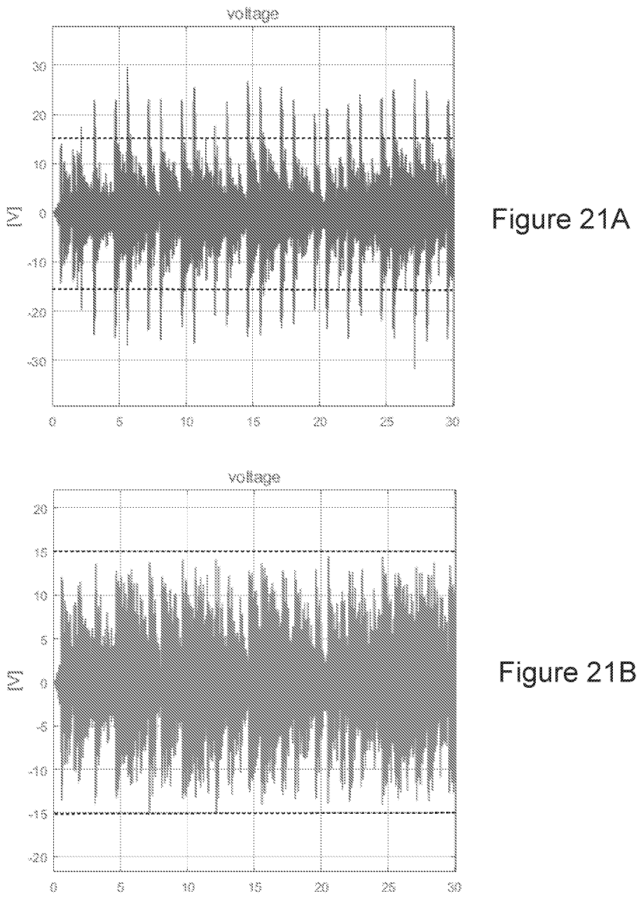

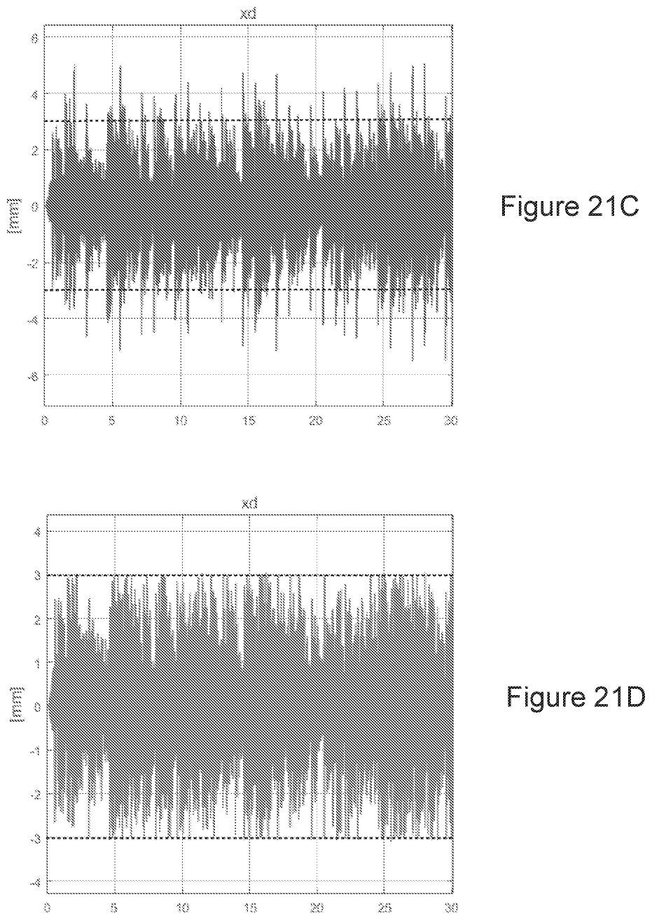

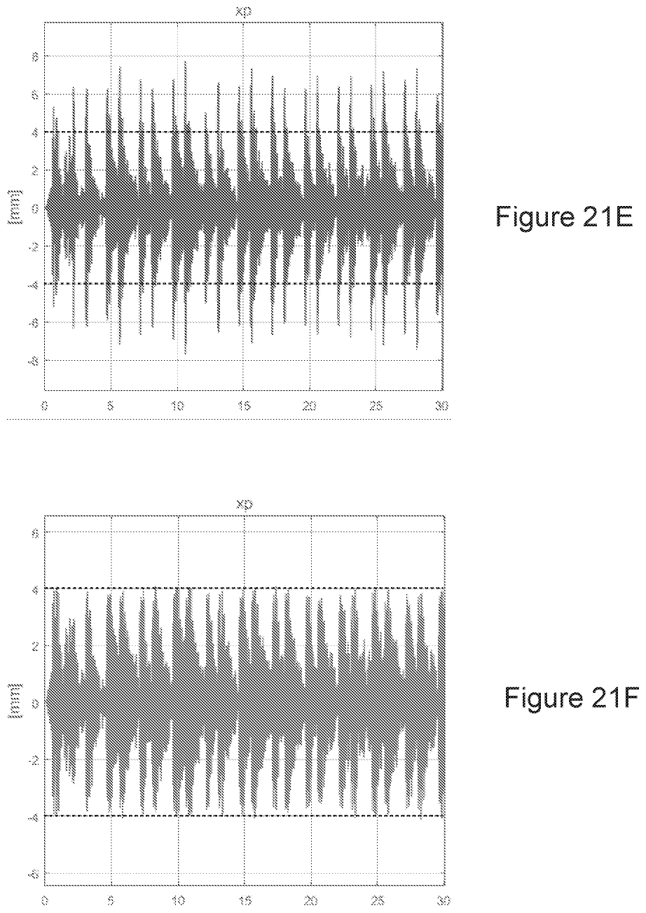

FIGS. 21A-21F are signal diagrams illustrating an example with music input of the hybrid system and method for signal processing to provide mechanical protection in the PR loudspeaker system 900 shown in FIG. 19. In the example shown, the protection setup includes an x_{d} limit of +/−3 mm, an xₚ limit of +/−4 mm, and voltage limit of 15V. The signals as a function of time show unprotected voltage, xd, and xp, as well as protected voltage, xd, and xp after signal processing according to the hybrid system and method of FIG. 19. More specifically, FIG. 21A shows the unprotected varying input voltage of an audio signal representing an audible sound that is received by the side-chain limiter block 902, which may exceed the voltage protection limit (+/−15V). FIG. 21B shows the protected varying output voltage produced by the nonlinear inverse PR system model module 918 and provided to the PR loudspeaker 900 for reproduction of the audible sound, which output voltage is consistently within that voltage protection limit.

FIG. 21C shows unprotected xa values produced by the linear PR model module 914, which may exceed the x_{d} protection limit (+/−3 mm), while FIG. 21D shows the protected x_{d} values produced by the peak limiter 916 and the nonlinear inverse PR system model module 918, which x_{d} values are consistently within that x_{d} protection limit. Finally, FIG. 21E shows unprotected xₚ values produced by the linear PR model module 906, which may exceed the xₚ protection limit (+/−4 mm), while FIG. 21F shows the protected xₚ values produced by the side-chain block 910, which xₚ values are consistently within that xₚ protection limit.

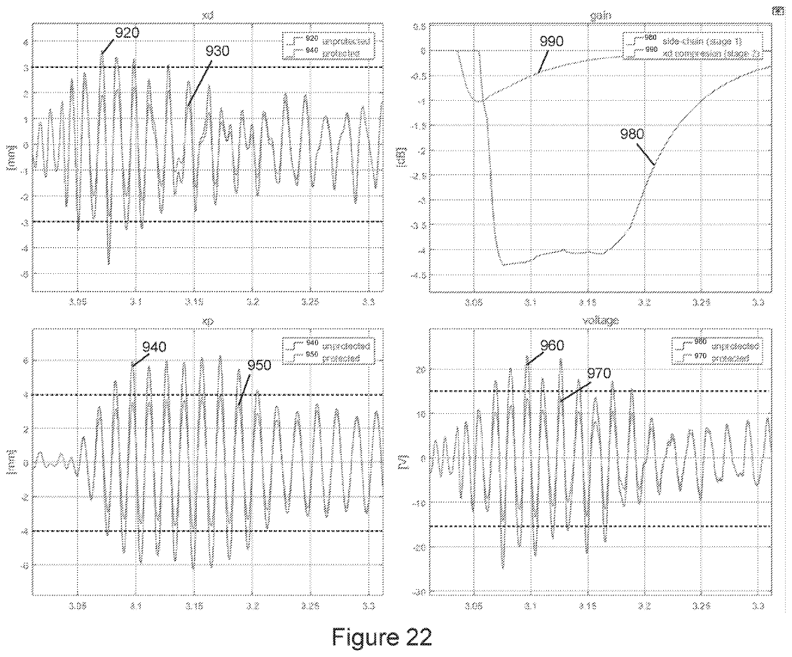

FIG. 22 depicts signal diagrams illustrating an example with music input of the hybrid method for signal processing to provide mechanical protection in a passive radiator loudspeaker system shown in FIG. 19. While FIGS. 21A-21F shows the signals noted over time from 0-10 seconds, FIG. 22 shows those same signals zoomed in at approximately the 3.2 second mark. Thus, the upper left graph of FIG. 22 once again shows unprotected xd values 920, which may exceed the xd protection limit (+/−3 mm), along with the protected xd values 930 that are consistently within that xd protection limit. The lower left graph of FIG. 22 again shows unprotected xₚ values 940, which may exceed the xp protection limit (+/−4 mm), along with the protected xₚ values 950 that are consistently within that xp protection limit. The lower right graph of FIG. 22 again shows unprotected voltage values 960, which may exceed the voltage protection limit (+/−15V), along with protected xₚ values 970 that are consistently within that voltage protection limit. Finally, the upper right graph of FIG. 22 shows side-chain (Stage 1) computed gain 980 and directed compression (Stage 2) computed gain 990.

According to another non-limiting, exemplary embodiment, the present disclosure also provides for multi-band and multi-stage protection. In that regard, dynamic range processing is preferred for each frequency band separately (i.e., the multi-band DRC) with different tuning parameters. This avoids problems like pumping and gain modulation. All previously introduced methods and systems for mechanical protection according to the present disclosure can be used in a multi-band structure.

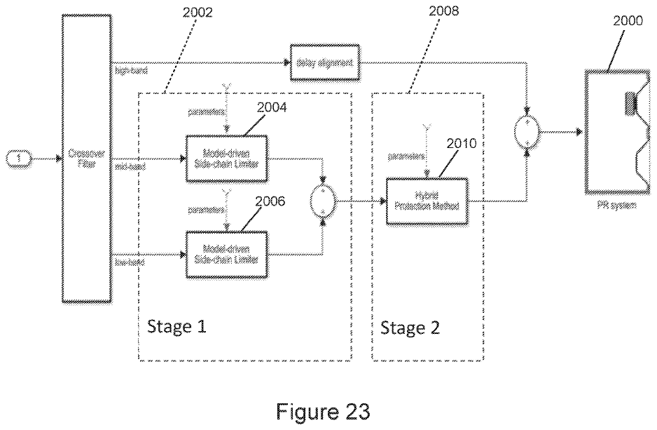

FIG. 23 is a simplified block diagram of multi-band and multi-stage protection for a PR loudspeaker system 2000 according to a non-limiting, exemplary alternative embodiment of the systems and methods of the present disclosure. As seen therein, a Stage 1 block 2002 may comprise a mid-band model-driven side-chain limiter module 2004 and a low-band model-driven side-chain limiter module 2006, such as previously described herein. After the Stage 1 block 2002 with the multi-band limiters 2004, 2006, a wider-band protection is follows in a Stage 2 block 2008 to ensure that the total signal is within the mechanical limit. In that regard, the Stage 2 block 2008 may comprise a hybrid protection method 2010, such as previously described herein. Since most compressions take place in the Stage 1 block 2002, the gain at the Stage 2 block 2008 will not produce any audible artifacts. The protection limits for each band at the Stage 1 block 2002 can be either fixed or adaptive depending on the input signal.

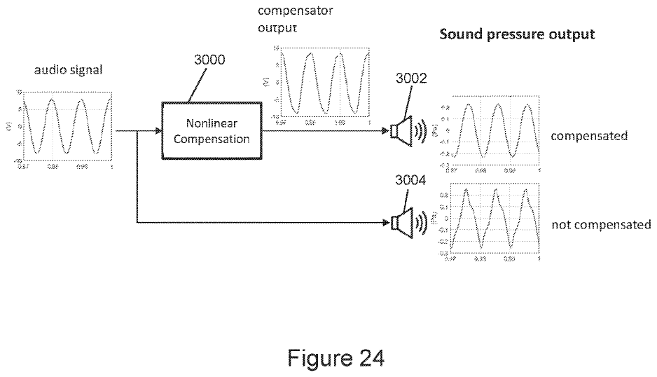

The systems and methods according to the present disclosure also provide for nonlinear compensation. In that regard, FIG. 24 is a simplified block diagram of a concept of nonlinear compensation of a loudspeaker. As seen therein, a nonlinear filter or nonlinear controller 3000 provides nonlinear compensation to pre-distort the varying input signal (measured in volts) to a loudspeaker 3002 in a way that the distortions of the overall system (i.e., sound pressure output, measured in Pascals (Pa)) are reduced in comparison to a non-distorted input signal provided to a loudspeaker 3004. Nonlinear compensation improves the sound quality at high volume and extends maximum bass output by exploiting the nonlinear working range of the loudspeakers. Nonlinear compensations are essentially done by first finding an algebraic link between the input and the output (the model), and then writing an expression that inverses this link (the control law). The application of nonlinear compensation to loudspeakers is well known to those of ordinary skill. Exact methods differ in the models used for deriving the control law, and how the state information is obtained.

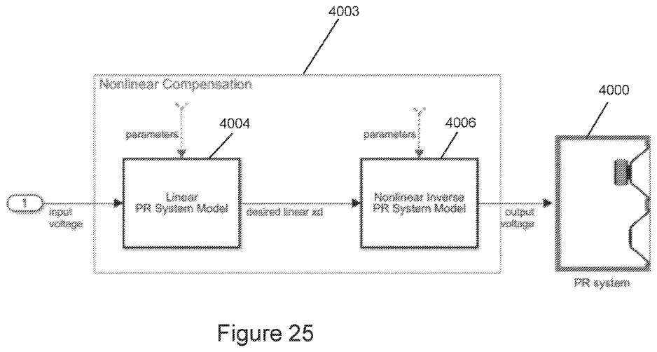

FIG. 25 is a simplified block diagram of nonlinear compensation for a PR loudspeaker system 4000 according to a non-limiting, exemplary embodiment of the present disclosure. As seen therein, a nonlinear compensation block 4002 may comprise a linear PR system model module 4004 that converts a varying input voltage of an audio signal representing an audible sound to a desired linear driver displacement, x_{d}. The linear PR system model module 4004 may or may not receive model parameter updates from outside. The nonlinear compensation block 4002 may further comprise a nonlinear inverse PR system model module 4006 that converts the desired linear x_{d} to a varying output voltage that is provided to the PR loudspeaker system 4000 to reproduce the audible sound. The nonlinear inverse PR system model module 4006 may or may not receive model parameter updates from outside. Thus, the linear model provides the desired linear displacement, and the inverse model can specify the voltage needed to produce the target displacement.

The systems and methods of the present disclosure shown in FIG. 25 provide a novel extension to PR and vented-box systems, as well as close integration with mechanical protection, building on a known algorithm where the loudspeaker system was discretized first and then inverted. In that regard, the low-frequency dynamics of the PR system can be described by a lumped-parameter model. The model for vented-box is very similar. According to the present disclosure, by extending a known method, the physical model may be discretized for computing x_{d}, xₚ, and their inverse. It is noted, however, that the loudspeaker modeling methods and algorithms present herein are not the only types that may be utilized. Any other methods or algorithms that model a loudspeaker system and its inverse with sufficient accuracy may be used in the systems and methods of the present disclosure for mechanical protection and nonlinear compensation as described herein.

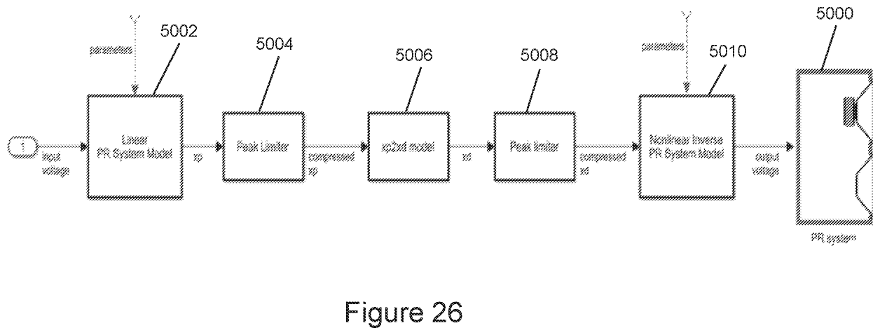

According to the present disclosure, nonlinear compensation may be integrated with mechanical protection. FIG. 26 is a simplified block diagram of nonlinear compensation integration with direct mechanical compression in a PR loudspeaker system 5000 according to a non-limiting, exemplary embodiment of the method and system of the present disclosure. As seen therein, the system may comprise a linear PR system model module 5002 that produces xₚ from input voltage of an audio signal representing an audible sound and which may or may not receive parameter updates from outside. The system may also comprise a peak limiter 5004 that compresses the xₚ signal, and a xₚ-to-x_{d} model module 5006 that converts the compressed xₚ signal to the corresponding x_{d} signal. The system may further comprise a peak limiter 5008 that compresses the x_{d} signal, and a nonlinear inverse PR system model module 5010 that converts x_{d} back to an output voltage to be provided to the PR loudspeaker system 5000 to reproduce the audible sound. The nonlinear inverse PR system model module 5010 may or may not receive model parameter updates from outside. In that regard, it is noted that by inserting limiters 5004, 5008 between the linear model module 5002 and the inverse model module 5010, the nonlinear compensation becomes basically the same as the direct mechanical compression method for mechanical protection, shown in FIGS. 13A and 13B. A main difference is that for the purpose of mechanical protection in FIGS. 13A and 13B, the inverse model module 710 could be linear, whereas the inverse model module 5010 of FIG. 26 must be nonlinear for nonlinear compensation.

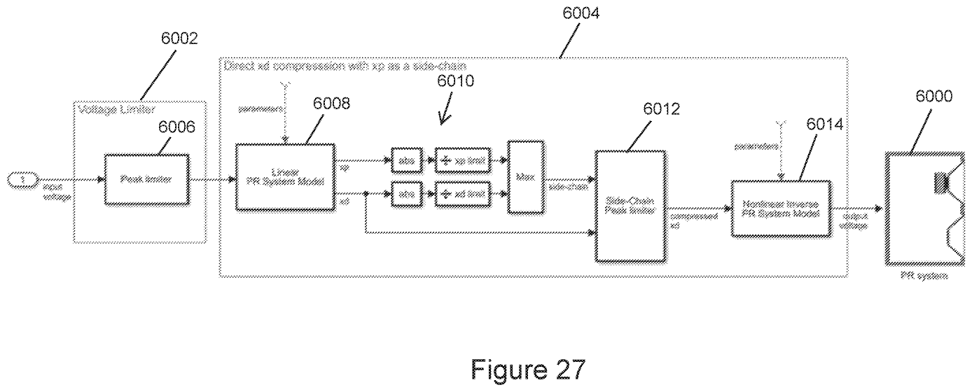

FIG. 27 is a simplified block diagram of nonlinear compensation integration with a hybrid method of direct compression of x_{d} and side-chain limiting for xₚ in a PR loudspeaker system 6000 according to a non-limiting, exemplary embodiment of the method and system of the present disclosure. As seen therein, the system may comprise a voltage limiter 6002 and a direct compression block 6004 with xₚ (and x_{d}) as a side-chain. The voltage limiter 6002 may comprise a peak limiter 6006 for limiting and/or compressing a varying input voltage of an audio signal representing an audible sound. The direct compression block 6004 may comprise a linear PR system model module 6008, which is a digital model that produces x_{d} and xₚ from the input voltage received from the voltage limiter 6002. The module 6008 may or may not receive model parameter updates from outside, and may be linear or nonlinear depending on the needs.

The direct compression block 6004 may further comprise a side-chain block 6010 for computing xₚ and x_{d} side-chains. The side-chain block 6010 may, for each signal (xₚ, x_{d}), take the absolute value and then normalize it by a corresponding threshold (limit). The largest value among the two (xₚ, x_{d}) is the side-chain input to a peak limiter 6012, which detects the peak values exceeding the corresponding threshold and outputs a compressed x_{d}. The direct compression block 6004 may further comprise a nonlinear inverse PR system model module 6014 that converts the compressed x_{d} received from the peak limiter 6012 to a varying output voltage, which is provided to the PR loudspeaker system 6000 for reproduction of the audible signal. The module 6014 may or may not receive model parameter updates from outside.

Here again, it is noted that by inserting the side-chain block 6010, 6012 between the linear model module 6008 and the nonlinear inverse model module 6014, the nonlinear compensation becomes basically the same as the direct mechanical compression method for mechanical protection shown in FIG. 20. Once again, a main difference is that for the purpose of mechanical protection in FIG. 20, the inverse model module 1014 could be linear, whereas the inverse model module 6014 of FIG. 27 must be nonlinear for nonlinear compensation.

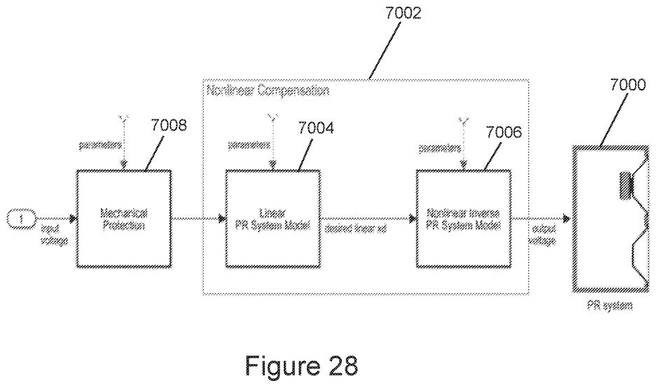

FIG. 28 is a simplified block diagram of nonlinear compensation integration with mechanical protection for a PR loudspeaker system 7000 according to another non-limiting, exemplary embodiment of the method and system of the present disclosure. As seen therein, a nonlinear compensation block 7002, which may comprise a linear PR system model module 7004 and a nonlinear inverse PR system model module 7006 as previously described herein, may be cascaded after a mechanical protection block 7008. In that regard, the mechanical protection block 7008 could be either side-chain based or direct mechanical compression, as previously described herein, and must precede the nonlinear compensation block 7002. Additionally, in general, there should not be any processing, either linear or nonlinear, between the nonlinear inverse model module 7006 and the PR loudspeaker system 7000, except simple gains like an amplifier.

As those skilled in the art will understand, the loudspeaker(s), controller(s), block(s), model(s), module(s), limiter(s), converter(s), compensator(s), compressor(s), technique(s), as well as any other component, system, subsystem, unit, method, interface, sensor, device, or the like described herein may individually, collectively, or in any combination comprise appropriate circuitry, such as one or more appropriately programmed processors (e.g., one or more microprocessors including central processing units (CPU)) and associated memory, which may include stored operating system software, firmware, and/or application software executable by the processor(s) for controlling operation thereof, any loudspeaker, block, model, module, limiter, converter, compensator, component, compressor, technique, system, subsystem, unit, method, interface, sensor, device, or the like described herein, and/or for performing the particular algorithm or algorithms represented by the various methods, functions, techniques, and/or operations described herein, including interaction between and/or cooperation with each other.

Item 1: According to an embodiment, the present disclosure provides a loudspeaker protection system comprising a loudspeaker comprising a driver and either a passive radiator or a vent port, and a controller configured to determine a displacement of the driver and either a displacement of the passive radiator or a velocity of airflow through the vent port based on an input voltage representing an audible sound, and to determine an output voltage for the loudspeaker to reproduce the audible sound based on a first type of compression applied to the driver displacement and a second type of compression applied to either the passive radiator displacement or the vent port airflow velocity, the second type of compression different than the first type of compression, wherein the output voltage provided to the loudspeaker limits the driver displacement within a driver displacement range and simultaneously limits either the passive radiator displacement within a passive radiator displacement range or the vent port airflow velocity within a vent port airflow velocity range to mechanically protect the loudspeaker and reduce distortions in the audible sound reproduced by the loudspeaker.

Item 2: In another embodiment, the present disclosure provides the loudspeaker protection system according to Item 1 wherein the controller comprises a dynamic range controller and the first type of compression comprises direct compression, the dynamic range controller comprising a loudspeaker model module configured to convert the input voltage to the driver displacement, a peak limiter configured to compress the driver displacement, and an inverse loudspeaker model module configured to convert the compressed driver displacement to the output voltage for the loudspeaker.

Item 3: In another embodiment, the present disclosure provides the loudspeaker protection system according to Item 1 or Item 2 wherein the controller comprises a dynamic range controller and the second type of compression comprises side-chain dynamic range compression, the dynamic range controller comprising a loudspeaker model module configured to convert the input voltage to either the passive radiator displacement or the vent port airflow velocity, and a side-chain peak limiter configured to determine the output voltage for the loudspeaker based on either the passive radiator displacement or the vent port airflow velocity.

Item 4: In another embodiment, the present disclosure provides the loudspeaker protection system according to any of Items 1-3 further comprising a compensator configured to apply nonlinear compensation to the output voltage to produce a compensated output voltage for the loudspeaker.

Item 5: In another embodiment, the present disclosure provides the loudspeaker protection system according to any of Items 1-4 wherein the input voltage comprises a plurality of input voltages each representing a frequency from a different one of a plurality of frequency bands of the audible sound, and wherein the controller is configured to determine a displacement of the driver and either a displacement of the passive radiator or a velocity of airflow through the vent port based on each one of the plurality of input voltages.

Item 6: In another embodiment, the present disclosure provides the loudspeaker protection system according Item 2 wherein the loudspeaker model and the inverse loudspeaker model module receive updated loudspeaker parameters.

Item 7: In another embodiment, the present disclosure provides the loudspeaker protection system according to Item 3 wherein the loudspeaker model module receives updated loudspeaker parameters.

Item 8: According to an embodiment, the present disclosure provides a method for mechanically protecting a loudspeaker comprising a driver and either a passive radiator or a vent port, the method comprising determining a displacement of the driver and either a displacement of the passive radiator or a velocity of airflow through the vent port based on an input voltage representing an audible sound, determining an output voltage for the loudspeaker to reproduce the audible sound based on a first type of compression applied to the driver displacement and a second type of compression applied to either the passive radiator displacement or the vent port airflow velocity, the second type of compression different than the first type of compression, and providing the output voltage to the loudspeaker to limit the driver displacement within a driver displacement range and to simultaneously limit either the passive radiator displacement within a passive radiator displacement range or the vent port airflow velocity within a vent port airflow velocity range to mechanically protect the loudspeaker and reduce distortions in the audible sound reproduced by the loudspeaker.

Item 9: In another embodiment, the present disclosure provides the method for mechanically protecting a loudspeaker according to Item 8 wherein the first type of compression comprises direct compression, the method further comprising converting, via a loudspeaker model, the input voltage to the driver displacement, compressing the driver displacement, and converting, via an inverse loudspeaker model, the compressed driver displacement to the output voltage for the loudspeaker.

Item 10: In another embodiment, the present disclosure provides the method for mechanically protecting a loudspeaker according to Item 8 or 9 wherein the second type of compression comprises side-chain dynamic range compression, the method further comprising converting, via a loudspeaker model, the input voltage to either the passive radiator displacement or the vent port airflow velocity, and determining, via a side-chain peak limiter, the output voltage for the loudspeaker based on either the passive radiator displacement or the vent port airflow velocity.

Item 11: In another embodiment, the present disclosure provides the method for mechanically protecting a loudspeaker according to any of Items 8-10 further comprising applying nonlinear compensation to the output voltage to produce a compensated output voltage for the loudspeaker.

Item 12: In another embodiment, the present disclosure provides the method for mechanically protecting a loudspeaker according to any of Items 8-11 wherein the input voltage comprises a plurality of input voltages each representing a frequency from a different one of a plurality of frequency bands of the audible sound, and wherein determining a displacement of the driver and either a displacement of the passive radiator or a velocity of airflow through the vent port based on an input voltage representing an audible sound comprises determining a displacement of the driver and either a displacement of the passive radiator or a velocity of airflow through the vent port based on each one of the plurality of input voltages.

Item 13: In another embodiment, the present disclosure provides the method for mechanically protecting a loudspeaker according to Item 9 wherein the loudspeaker model and the inverse loudspeaker model are based on updated loudspeaker parameters.

Item 14: In another embodiment, the present disclosure provides the method for mechanically protecting a loudspeaker according to Item 10 wherein the loudspeaker model is based on updated loudspeaker parameters.

Item 15: According to an embodiment, the present disclosure provides a non-transitory computer readable medium having stored computer executable instructions for mechanically protecting a loudspeaker comprising a driver and either a passive radiator or a vent port, wherein execution of the instructions causes a controller to determine a displacement of the driver and either a displacement of the passive radiator or a velocity of airflow through the vent port based on an input voltage representing an audible sound, determine an output voltage for the loudspeaker to reproduce the audible sound based on a first type of compression applied to the driver displacement and a second type of compression applied to either the passive radiator displacement or the vent port airflow velocity, the second type of compression different than the first type of compression, and provide the output voltage to the loudspeaker to limit the driver displacement within a driver displacement range and to simultaneously limit either the passive radiator displacement within a passive radiator displacement range or the vent port airflow velocity within a vent port airflow velocity range to mechanically protect the loudspeaker and reduce distortions in the audible sound reproduced by the loudspeaker.

Item 16: In another embodiment, the present disclosure provides the non-transitory computer readable medium according to Item 15 wherein the first type of compression comprises direct compression, and wherein execution of the instructions further causes the controller to convert, via a loudspeaker model, the input voltage to the driver displacement, compress the driver displacement, and convert, via an inverse loudspeaker model, the compressed driver displacement to the output voltage for the loudspeaker.

Item 17: In another embodiment, the present disclosure provides the non-transitory computer readable medium according to Item 15 or Item 16 wherein the second type of compression comprises side-chain dynamic range compression, and wherein execution of the instructions further causes the controller to convert, via a loudspeaker model, the input voltage to either the passive radiator displacement or the vent port airflow velocity, and determine, via a side-chain peak limiter, the output voltage for the loudspeaker based on either the passive radiator displacement or the vent port airflow velocity.

Item 18: In another embodiment, the present disclosure provides the non-transitory computer readable medium according to any of Items 15-17 wherein execution of the instructions further causes the controller to apply nonlinear compensation to the output voltage to produce a compensated output voltage for the loudspeaker.

Item 19: In another embodiment, the present disclosure provides the non-transitory computer readable medium according to Item 16 wherein the loudspeaker model and the inverse loudspeaker model are based on updated loudspeaker parameters.

Item 20: In another embodiment, the present disclosure provides the non-transitory computer readable medium according to Item 17 wherein the loudspeaker model is based on updated loudspeaker parameters.

The present disclosure provides methods and systems for mechanical protection and nonlinear compensation for Vented-box or PR Loudspeaker systems. With the methods and systems of the present disclosure, such loudspeaker systems can be safely pushed to their mechanical limits without the risk of being damaged. The nonlinear distortions can be actively reduced to exploit the nonlinear working range. Comparing to known methods or systems, the methods and systems of the present disclosure can simultaneously protect displacement of the loudspeaker driver and PR, as well as the vent velocity, and are well integrated with nonlinear compensation. The methods and systems of the present disclosure can potentially be used for loudspeaker systems of any size, ranging from portable products to large subwoofers, and result in a huge and clean bass produced from a loudspeaker with a relatively a small form factor that performs beyond user expectations.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

1. A loudspeaker protection system comprising:
a loudspeaker comprising a driver and either a passive radiator or a vent port; and
a controller configured to determine a displacement of the driver and either a displacement of the passive radiator or a velocity of airflow through the vent port based on an input voltage representing an audible sound, and to determine an output voltage for the loudspeaker to reproduce the audible sound based on a first type of compression applied to the driver displacement and a second type of compression applied to either the passive radiator displacement or the vent port airflow velocity, the second type of compression different than the first type of compression;
wherein the output voltage provided to the loudspeaker limits the driver displacement within a driver displacement range and simultaneously limits either the passive radiator displacement within a passive radiator displacement range or the vent port airflow velocity within a vent port airflow velocity range to mechanically protect the loudspeaker and reduce distortions in the audible sound reproduced by the loudspeaker.

2. The loudspeaker protection system according to claim 1 wherein the controller comprises a dynamic range controller and the first type of compression comprises direct compression, the dynamic range controller comprising:
a loudspeaker model module configured to convert the input voltage to the driver displacement;
a peak limiter configured to compress the driver displacement; and
an inverse loudspeaker model module configured to convert the compressed driver displacement to the output voltage for the loudspeaker.

3. The loudspeaker protection system according to claim 1 wherein the controller comprises a dynamic range controller and the second type of compression comprises side-chain dynamic range compression, the dynamic range controller comprising:
a loudspeaker model module configured to convert the input voltage to either the passive radiator displacement or the vent port airflow velocity; and
a side-chain peak limiter configured to determine the output voltage for the loudspeaker based on either the passive radiator displacement or the vent port airflow velocity.

4. The loudspeaker protection system according to claim 1 further comprising a compensator configured to apply nonlinear compensation to the output voltage to produce a compensated output voltage for the loudspeaker.

5. The loudspeaker protection system according to claim 1 wherein the input voltage comprises a plurality of input voltages each representing a frequency from a different one of a plurality of frequency bands of the audible sound, and wherein the controller is configured to determine a displacement of the driver and either a displacement of the passive radiator or a velocity of airflow through the vent port based on each one of the plurality of input voltages.

6. The loudspeaker protection system according to claim 2 wherein the loudspeaker model and the inverse loudspeaker model module receive updated loudspeaker parameters.

7. The loudspeaker protection system according to claim 3 wherein the loudspeaker model module receives updated loudspeaker parameters.

8. A method for mechanically protecting a loudspeaker comprising a driver and either a passive radiator or a vent port, the method comprising:
determining a displacement of the driver and either a displacement of the passive radiator or a velocity of airflow through the vent port based on an input voltage representing an audible sound;
determining an output voltage for the loudspeaker to reproduce the audible sound based on a first type of compression applied to the driver displacement and a second type of compression applied to either the passive radiator displacement or the vent port airflow velocity, the second type of compression different than the first type of compression; and
providing the output voltage to the loudspeaker to limit the driver displacement within a driver displacement range and to simultaneously limit either the passive radiator displacement within a passive radiator displacement range or the vent port airflow velocity within a vent port airflow velocity range to mechanically protect the loudspeaker and reduce distortions in the audible sound reproduced by the loudspeaker.

9. The method for mechanically protecting a loudspeaker according to claim 8 wherein the first type of compression comprises direct compression, the method further comprising:
converting, via a loudspeaker model, the input voltage to the driver displacement;
compressing the driver displacement; and
converting, via an inverse loudspeaker model, the compressed driver displacement to the output voltage for the loudspeaker.

10. The method for mechanically protecting a loudspeaker according to claim 8 wherein the second type of compression comprises side-chain dynamic range compression, the method further comprising:
converting, via a loudspeaker model, the input voltage to either the passive radiator displacement or the vent port airflow velocity; and
determining, via a side-chain peak limiter, the output voltage for the loudspeaker based on either the passive radiator displacement or the vent port airflow velocity.

11. The method for mechanically protecting a loudspeaker according to claim 8 further comprising applying nonlinear compensation to the output voltage to produce a compensated output voltage for the loudspeaker.

12. The method for mechanically protecting a loudspeaker according to claim 8 wherein the input voltage comprises a plurality of input voltages each representing a frequency from a different one of a plurality of frequency bands of the audible sound, and wherein determining a displacement of the driver and either a displacement of the passive radiator or a velocity of airflow through the vent port based on an input voltage representing an audible sound comprises determining a displacement of the driver and either a displacement of the passive radiator or a velocity of airflow through the vent port based on each one of the plurality of input voltages.

13. The method for mechanically protecting a loudspeaker according to claim 9 wherein the loudspeaker model and the inverse loudspeaker model are based on updated loudspeaker parameters.

14. The method for mechanically protecting a loudspeaker according to claim 10 wherein the loudspeaker model is based on updated loudspeaker parameters.

15. A non-transitory computer readable medium having stored computer executable instructions for mechanically protecting a loudspeaker comprising a driver and either a passive radiator or a vent port, wherein execution of the instructions causes a controller to:
determine a displacement of the driver and either a displacement of the passive radiator or a velocity of airflow through the vent port based on an input voltage representing an audible sound;
determine an output voltage for the loudspeaker to reproduce the audible sound based on a first type of compression applied to the driver displacement and a second type of compression applied to either the passive radiator displacement or the vent port airflow velocity, the second type of compression different than the first type of compression; and
provide the output voltage to the loudspeaker to limit the driver displacement within a driver displacement range and to simultaneously limit either the passive radiator displacement within a passive radiator displacement range or the vent port airflow velocity within a vent port airflow velocity range to mechanically protect the loudspeaker and reduce distortions in the audible sound reproduced by the loudspeaker.

16. The non-transitory computer readable medium according to claim 15 wherein the first type of compression comprises direct compression, and wherein execution of the instructions further causes the controller to:
convert, via a loudspeaker model, the input voltage to the driver displacement;
compress the driver displacement; and
convert, via an inverse loudspeaker model, the compressed driver displacement to the output voltage for the loudspeaker.

17. The non-transitory computer readable medium according to claim 15 wherein the second type of compression comprises side-chain dynamic range compression, and wherein execution of the instructions further causes the controller to:
convert, via a loudspeaker model, the input voltage to either the passive radiator displacement or the vent port airflow velocity; and
determine, via a side-chain peak limiter, the output voltage for the loudspeaker based on either the passive radiator displacement or the vent port airflow velocity.

18. The non-transitory computer readable medium according to claim 15 wherein execution of the instructions further causes the controller to apply nonlinear compensation to the output voltage to produce a compensated output voltage for the loudspeaker.

19. The non-transitory computer readable medium according to claim 16 wherein the loudspeaker model and the inverse loudspeaker model are based on updated loudspeaker parameters.

20. The non-transitory computer readable medium according to claim 17 wherein the loudspeaker model is based on updated loudspeaker parameters.
